(19) United States
(12) Patent Application Publication
(10) Pub. No.: US 2005/0117442 A1
(43) Pub. Date: Jun. 2, 2005

(54) Integrated semiconductor memory

(76) Inventor: Michael Bernhard Sommer, Raubling (DE)

Correspondence Address: EDELL, SHAPIRO, FINNAN & LYTLE, LLC, 1901 RESEARCH BOULEVARD, SUITE 400, ROCKVILLE, MD, 20850, US

(21) Appl. No.: 10/980,151

(22) Filed: Nov. 4, 2004

(30) Foreign Application Priority Data
Nov. 5, 2003 (DE) 10351605.0

(51) Int. Cl. G11C 8/02

(52) U.S. Cl. 365/232

(57) ABSTRACT

An integrated semiconductor memory can have a memory cell with a storage capacitor and a selection transistor, which can be driven by a bit line and a word line. The selection transistor can have a region made of semiconductor material, which adjoins a gate dielectric, in which a transistor channel can be formed, and into which is introduced a source/drain implantation with which electrical contact is made by the bit line. A Schottky contact is provided between the selection transistor and the storage capacitor. The region made of semiconductor material is free of dopants of a source/drain implantation proximate to the Schottky contact. By dispensing with a source/drain implantation on the capacitor side, leakage currents are reduced and the write and read-out speed of the memory cell is increased.

### CROSS REFERENCE TO RELATED APPLICATIONS

This application claims priority under 35 USC §119 to German Application No. DE 103 51 605.0, filed on Nov. 5, 2003, and titled “Integrated Semiconductor Memory,” the entire contents of which are hereby incorporated by reference.

### FIELD OF THE INVENTION

The invention relates to an integrated semiconductor memory having a memory cell having a storage capacitor and a selection transistor, which can be driven by a bit line and a word line.

### BACKGROUND

Integrated semiconductor memories have a cell array having a multiplicity of memory cells in which electrical charges can be stored in storage capacitors. The transistor of the memory cell is situated at the crossover point of a bit line and a word line, which transistor is opened at corresponding chosen electrical potentials of the bit line and the word line and via which transistor digital information items in the form of charge quantities are written to the storage capacitor or are read from the latter. Due to this function, the transistor is often called a selection transistor. It is usually formed as a field effect transistor and is then formed at a layer sequence made of semiconductor material, gate dielectric and gate electrode. Two source/drain implantations usually introduced into the semiconductor material between which a transistor channel can form. The gate electrode often includes a plurality of layers and is formed, i.e., patterned, as an implantation mask between the two source/drain implantations. The width or length of the gate electrode parallel to the direction of the course of the gate dielectric along the path between one source/drain implantation and the other source/drain implantation prescribes the channel length of the transistor, particularly in the case of a planar design.

Ideally, no leakage currents flow in the transistor closed state of the memory cell, while in the transistor open state, the stored charge to flows relatively rapidly to the bit line or in the opposite direction. A sufficiently fast read-out and writing of digital information items to the storage capacitors of the memory cells is essential for an increased operating speed of a semiconductor memory.

In a real integrated semiconductor circuit for a semiconductor memory, however, leakage currents occur in the switched-off state of the transistor, for example, the subthreshold current, which, despite decreasing exponentially as the gate length increases in magnitude, nonetheless never entirely disappears. Moreover, with the advancing integration density of modern semiconductor memories, the gate or channel lengths become smaller and smaller, and subthreshold currents tend to increase. As a result, a part of the stored charge flows away relatively continuously through the transistor, as a result of which the refresh time is shortened.

Moreover, limits are imposed on the speed of writing to and reading from the storage capacitor. At least in the case of vertical selection transistors, i.e., selection transistors running perpendicular to the substrate surface, the electrical connection between that region of the transistor in which the transistor channel is formed and the storage capacitor electrode to be charged electrically is produced by a filling made of polysilicon which includes a dopant. During fabrication of the semiconductor memory,with a temperature increase, a part of the dopant emerges from the polysilicon filling and diffuses into a part of the region made of semiconductor material and thereby forms the source/drain electrode on the capacitor side in the region made of semiconductor material. The distance between this outdiffusion and the source/drain implantation on the bit line side then determines the channel length.

The doped polysilicon filling has a certain electrical resistance that limits the speed of reading from the memory cell or writing to the memory cell. This filling is nevertheless provided because the source/drain electrode on the capacitor side can only be produced by outdiffusion from the doped polysilicon into the region made of semiconductor material. In the case of this design, an increase in the memory speed or read-out speed could be achieved by an increased cross section of the polysilicon filling. However, this is at odds with the trend toward component structures having increasingly smaller dimensions.

Also, leakage currents due to the continuously flowing stored charge from the storage capacitor occur. One possible leakage mechanism runs from the source/drain electrode on the capacitor side through the substrate material of the semiconductor substrate as far as the buried external electrode common to the storage capacitors, i.e., the buried plate. In order to impede this leakage current path, the buried plate is introduced into the semiconductor substrate as deeply as possible. Above this external electrode of the storage capacitors, a thickened insulating material is provided at the trench wall of the storage capacitor or in a corresponding region of a stacked capacitor. This collar prevents shorter leakage current paths, but also shifts the top side of the trench capacitor deeper into the semiconductor substrate. The position thereof is prescribed by the comparatively thin capacitor dielectric, at whose interfaces the stored charges and induced countercharges are for the most part situated. The comparatively large depth of the buried external electrode of the storage capacitors below the substrate surface, selected to avoid leakage currents between the source/drain implantation on the capacitor side and the external electrode, leads to insulation collars extending correspondingly deep into the substrate, thereby reducing the remaining residual depth for the formation of the capacitor and thus the capacitance. At the same time, the distance between the selection transistor and the storage capacitor increases; writing and read-out takes longer than is actually possible.

A semiconductor memory with a memory cell in which information items can be written in or read out more rapidly and is less susceptible to leakage currents occurring, is desirable. In particular, the subthreshold current is reduced when the transistor is switched off.

### SUMMARY

In an integrated semiconductor memory, a Schottky contact is provided between the selection transistor and the storage capacitor, and the region of the semiconductor material is free of dopants of a source/drain implantation in the vicinity of the Schottky contact.

According to the invention, a Schottky contact to a metallic contact connection is an electrical connection between the selection transistor and the storage capacitor. An electrical connection is conventionally formed at the capacitor-side interface of the region made of semiconductor material usually by the dopant diffusion. According to the invention, in circuitry terms, a diode that is normally off is arranged at the boundary between the region made of semiconductor material in which the channel is formed and the metallic contact connection. At the same time, since the metallic contact connection has no dopant in contrast to the conventional filling made of doped polysilicon, a source/drain implantation on the capacitor side is not formed during the production of the semiconductor circuit. This implantation is dispensed with according to the invention.

The design of a memory cell does not provide a separate structure for the source/drain electrode on the capacitor side. The source/drain electrode is formed by the metallic contact connection itself. The invention is furthermore based on the idea of electrically switching the normally off Schottky diode with the aid of the remaining electrodes of the selection transistor, i.e., opening it in order to effect storage in and reading from the memory cell.

Dispensing with the source/drain implantation on the capacitor side, which, in conventional semiconductor circuits, diffuses a little in all directions after corresponding thermal treatment, increases the channel length of the transistor, i.e., the distance between the source/drain implantation on the bit line side and the contact connection to the storage capacitor. Owing to the greater distance, the subthreshold current decreases with otherwise identical dimensions of the memory cell and of the transistor. Furthermore, leakage currents to the buried common external electrode of the storage capacitors are significantly impeded because, in the region of the substrate material without the source/drain implantation on the capacitor side, only the comparatively weak intrinsic doping exists and the distance from the buried electrode to the Schottky contact is relatively greater than to an indiffused source/drain implantation on the capacitor side. Consequently, the buried electrode can be formed less deep in the substrate and, consequently, the insulation collar can be formed such that the insulation collar extends down less deeply. This reduces the distance to be covered by charge carriers between the storage capacitor and the selection transistor, which increases the read-out speed or memory speed.

The read-out and memory speed is further increased by the metallic contact connection, which has relatively higher electrical conductivity than the doped polysilicon that is conventionally used. Although the Schottky contact inherently represents an electrical resistance, it can be opened at suitable electrode potentials of the selection transistor, thereby reducing overall the electrical resistance between selection transistor and storage capacitor.

Accordingly, the selection transistor has no further source/drain implantation in the region made of semiconductor material apart from the source/drain implantation with which electrical contact is made by the bit line. This design is appropriate, in particular, for vertical selection transistors since, conventionally, the upper and lower source/drain implantations are not necessarily produced by one and/or the same method step.

The Schottky contact is formed between an interface of the region made of semiconductor material and a metallic contact connection. In this case, the semiconductor material that forms the substrate body or semiconductor body of the transistor for channel formation and the material of the metallic contact connection may directly adjoin one another. The diode formed, as a result, prevents charges from flowing back from the storage capacitor into the semiconductor material; leakage currents that would commence there do not occur.

The Schottky contact is formed, for instance, directly at an interface of the region made of semiconductor material.

The storage capacitor is a trench capacitor formed in a semiconductor substrate, and the selection transistor is arranged such that a transistor channel with a current flow direction running perpendicular to the substrate surface of the semiconductor substrate can be formed in the region made of semiconductor material. In this embodiment, the invention can be produced in terms of fabrication technology; there is no longer a heat treatment step conventionally required for forming the lower source/drain implantation. Instead of the electrical contact connection between the selection transistor and the inner electrode of the storage capacitor, which electrical contact connection conventionally includes doped polysilicon, a metallic contact connection is provided. As a result, the Schottky contact between the metallic contact and the region made of semiconductor material in which the transistor channel is formed is already completed. The fabrication of the upper source/drain implantations on the bit line side can be retained unchanged.

The region made of semiconductor material is formed in a pillar-type fashion and is covered on its periphery with the gate dielectric at a level above the metallic contact connection. In this case, the region made of semiconductor material is enclosed on all sides by the gate dielectric and the gate electrode in the lateral direction at the level of the transistor channel. As a result, higher channel currents are achieved due to the annular channel cross section, and further increase the memory and read-out speed. Accordingly, the region made of semiconductor material covered with the gate dielectric is surrounded annularly by the gate electrode.

In a state of the semiconductor memory in which the word line that drives the memory cell is not activated, the gate electrode is biased with an electrical potential at which the Schottky contact effects blocking and the storage capacitor is electrically insulated from the selection transistor. In this case, the electrical insulation of the storage capacitor from the source/drain zone on the bit line side is produced not only by the prevented transistor channel, but also by the blocking Schottky diode. This additional electrical insulation contributes to a lengthened storage duration. In the case of an n-channel transistor, for example, the gate electrode is biased negatively with respect to the metallic contact connection. The negative bias may be achieved by the electrical potential of the metallic contact connection and the capacitor electrode connected thereto being greater than the electrical potential of the gate electrode.

The Schottky contact and the gate electrode are arranged such that the Schottky contact is simultaneously opened when the gate electrode is biased to a gate potential suitable for opening the selection transistor. For this purpose, the gate electrode is configured such that charge transfers induced by the gate electrode open the Schottky contact, if the storage capacitor is intended to be read from or written to.

In particular, the gate electrode extends on the side of the region made of semiconductor material opposite the metallic contact connection into the level of the Schottky contact. In the case of this geometrical arrangement, the gate electrode extends to a level or depth below the channel region where, conventionally, the source/drain implantation on the capacitor side is arranged and, according to the invention, the Schottky contact is arranged. The Schottky contact and a lower region of the gate electrode are thus arranged on opposite sides of the semiconductor material in which the channel is formed. At this level, therefore, the electrically biased gate electrode arranged on one side brings about a band bending on the side of the Schottky contact. As a result, the Schottky contact can be opened and closed in a targeted manner through the gate potential. For example, if the semiconductor material in the region in which the channel is also formed is weakly p-doped, then a positive gate potential leads to the formation of a channel extending as far as the Schottky contact.

The region made of semiconductor material is part of the semiconductor substrate, and the word line is introduced into a trench surrounding the region of the semiconductor material. In this case, the pillar-type regions made of semiconductor material may be patterned by an etching process during which their surroundings are removed in the form of a longitudinal trench into which the word line is introduced later.

Finally, the selection transistor is a field effect transistor and the semiconductor memory is a dynamic random access memory.

### BRIEF DESCRIPTION OF THE DRAWINGS

The invention is described below with reference to FIGS. 1 to 5, in which:

FIG. 1 shows a cross-sectional view of the semiconductor memory according to the invention,

FIGS. 2A to 2D show a diagrammatic illustration of a layer sequence comprising metallic contact connection, semiconductor material, gate dielectric and gate electrode in the case of various potential conditions,

FIG. 3 shows a diagrammatic perspective illustration of the semiconductor memory according to the invention,

FIG. 4 shows a section through FIG. 1 at a first level H1, and

FIG. 5 shows a section through FIG. 1 at a second level H2.

### DETAILED DESCRIPTION

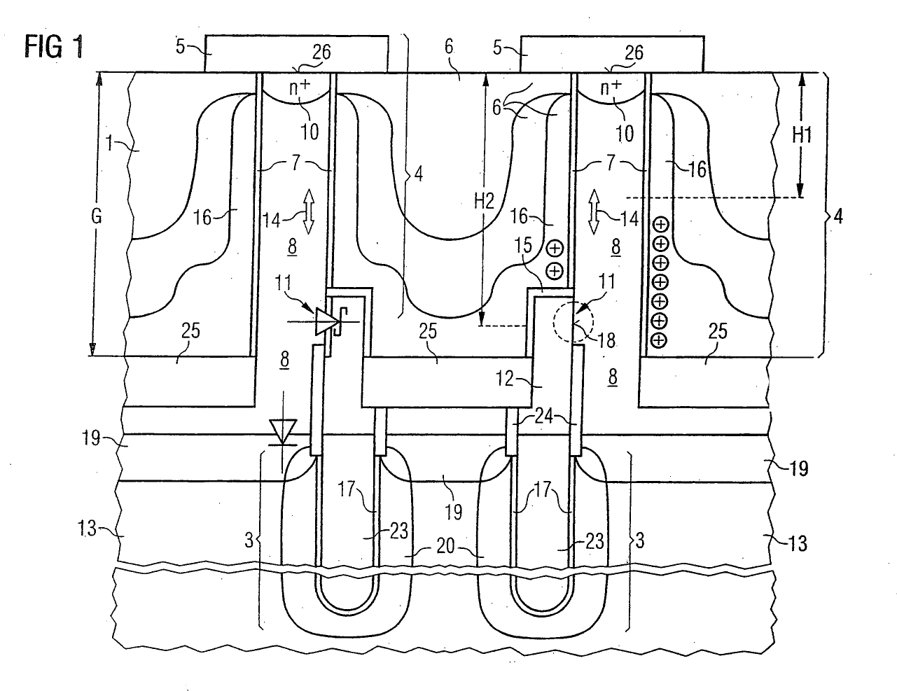

FIG. 1 shows a semiconductor memory 1 according to the invention, in which two memory cells are illustrated. The memory cells each have a selection transistor 4 connected to a bit line 5 by a source/drain terminal 10 on the bit line side. The bit line runs above the surface 26 of the semiconductor substrate 13. Each memory cell furthermore has a storage capacitor 3 formed as a trench capacitor, which storage capacitor has an inner capacitor electrode 23, an outer capacitor electrode 18, and a capacitor dielectric 17 in between. An isolation trench 24 surrounding a contact connection 12 is formed in an upper region of the storage capacitor 3. Isolation trenches 25 that prevent a crosstalk of adjacent memory cells are arranged at the level of the contact connection 12. The word line 6, which drives both memory cells illustrated, runs from left to right and thus perpendicular to the bit lines 5.

The region 8 made of semiconductor material in which the transistor channel is formed, at least in places, with a current direction along the double arrow 14 is also referred to as the “body” and, as illustrated in FIG. 1, may not be part of the semiconductor substrate 13. The “body,” for example, is produced by subsequently growing a monocrystalline layer onto an initially applied insulation layer, but is then electrically insulated from the semiconductor substrate.

Each region 8 made of semiconductor material is formed in pillar-type fashion in FIG. 1 and surrounded annularly along the pillar periphery by a gate dielectric 7. On the outer side of the gate dielectric 7 runs the gate electrode 16 or the word line 6. The gate electrode 16 or the word line 6 often include plurality of layers, as indicated in FIG. 1, for example, a lower layer made of polysilicon to which a tungsten-containing layer or a tungsten-containing layer sequence is applied. The word line 6 or the gate electrode 16 is covered by a planarizing nitride layer that can serve as insulation from the bit lines.

Unlike conventional semiconductor memories, the semiconductor memory according to the invention, which is illustrated in FIG. 1, does not have a source/drain implantation at the level of the contact area between the contact connection 12 and the region 8 made of semiconductor material. Instead, the region 8 made of semiconductor material is doped with the well doping, in the same way, for example, as the remaining regions of the semiconductor substrate 13. According to the invention, the connecting structure 12 is metallic, so that a Schottky diode is formed at the interface 8, and the diode is electrically insulated from the gate electrode 16 by an insulation 15 and by the isolation trenches 25, but is electrically influenced on the opposite side of the pillar-type bulk material, as illustrated in FIG. 1, based on the positively charged holes represented. At level H2 of the Schottky contact, the effect is that the transistor channel extends as far as the Schottky contact. As a result of this, the transistor channel is lengthened downward and the storage capacitor is opened. In the left-hand memory cell, the Schottky contact 11 is indicated by a circuit symbol.

A buried electrode plate 19 is arranged within the semiconductor substrate 13 and is short-circuited with the outer capacitor electrodes 20. Since the semiconductor memory according to the invention does not have a lower source/drain implantation, the buried electrode 19 can be positioned, relatively closer in the direction of the surface 26 than in the case of conventional semiconductor memories, in which, in such a position, there is an increased risk of leakage currents to the lower source/drain electrode. As a result, the isolation trench 24 may also be dimensioned such that the isolation trench 24 projects relatively less deeply into the capacitor trench and, consequently, the capacitor dielectric 17 extends relatively closer to the selection transistor 4. As a result of this, the storage capacitance of the storage capacitor is increased and, in addition, a faster read-out and storage of digital information items can be made possible.

In FIG. 1, the word line is produced as the filling of a trench G that was patterned such that the pillar-type regions 8 made of semiconductor material of the semiconductor substrate were maintained.

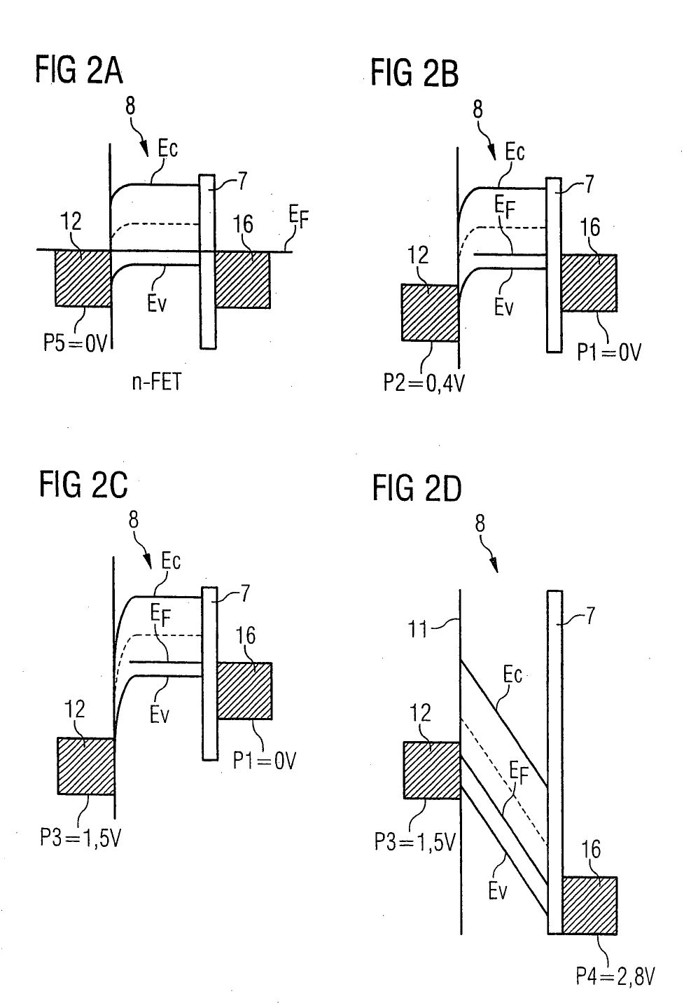

FIG. 2A diagrammatically shows the layer sequence includes metallic contact connection 12, the region 8 made of semiconductor material, the gate dielectric 7, and the gate electrode 6 in thermal equilibrium, at which the Fermi energy E_{F} is at the same level for each material. The metallic contact connection 12 and the gate electrode 6 are not electrically biased in this case. The band structure of the region 8 made of semiconductor material illustrated based on the lower conduction band edge Ec and the upper valence band edge Ev is slightly bent at the interface with the metallic contact connection 12, i.e., at the Schottky diode formed by the common interface. The layer sequence illustrated in the diagrammatic cross section, in FIGS. 2A to 2D is part of an n-channel transistor (n-FET).

FIG. 2B shows displacements of the band structure in the p-doped semiconductor material 8 when a potential P2 of the inner capacitor electrode and the metallic contact connection 12 correspond to a value of 0.4 V of a stored digital zero. The potential P1=0 V of the gate electrode 6 turns the transistor off and prevents the formation of a transistor channel. Compared with FIG. 2A, the electronic level of the electrons in the metallic contact connection 12 has decreased to the energetically positive potential P2=0.4 V.

FIG. 2C shows a corresponding potential profile in the case of a stored logic one, where, compared to FIG. 2B, the electrical potential P3=1.5 V of the metallic contact connection 12 has decreased energetically and the band structure in the semiconductor material 8 is therefore bent further even. The gate electrode 6 continues to be at a potential P1=0 V, which blocks the Schottky contact and electrically insulates the storage capacitor from the selection transistor.

If, as illustrated in FIG. 2D, the electrical potential of the gate electrode 6 is raised to a potential P4=2.8 V above the electrical potential P3=1.5 V of the metallic contact connection 12, then the electric field generated by the gate electrode 6 effects channel formation through to the Schottky contact. Due to the electric field, the band structure is distorted in the region 8 of the semiconductor material between the interface 11 at which the Schottky contact is formed and the gate dielectric 7. Electrons situated in the metallic contact connection 12 can pass into the semiconductor material 8 and be conducted away there through a transistor channel. The positively biased gate electrode 6 thus simultaneously opens the selection transistor and the Schottky diode. For the geometry illustrated in FIG. 1, in which, at level H2 of the Schottky contact 11, the gate electrode extends under the top side of the metallic contact connection 12, the electric field generated by the gate electrode 16 is directed relatively perpendicular to the interface 18 of the Schottky contact 11, as indicated by the horizontal arrows in FIG. 1.

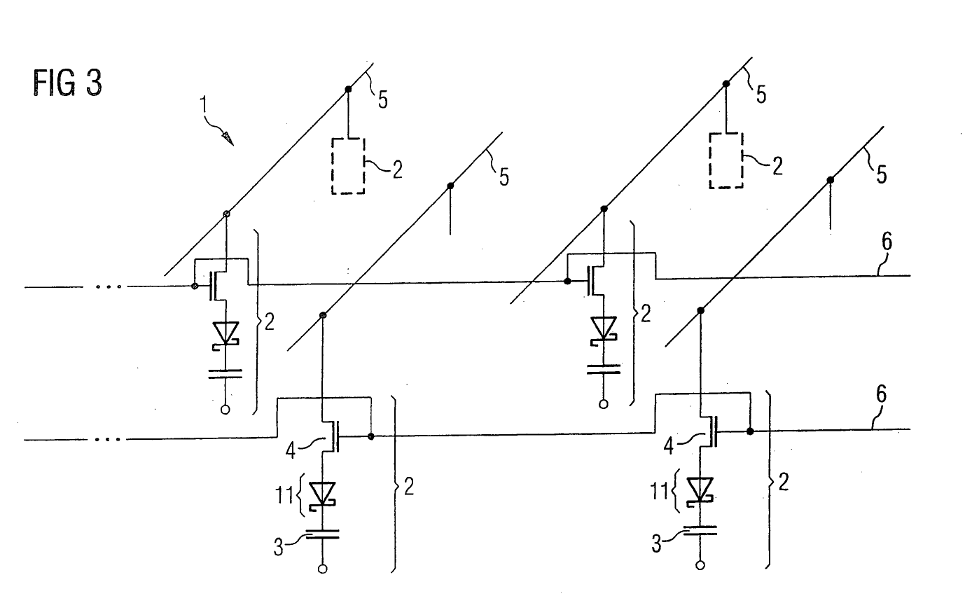

FIG. 3 shows a diagrammatic perspective view of a semiconductor memory 1 according to the invention. Memory cells 2 having a selection transistor 4, for example, a vertically arranged field effect transistor, and a storage capacitor 3 are provided at crossover points of word lines 6 and bit lines 5. The outer capacitor electrodes are electrically interconnected and electrically biased with a potential that is not specifically illustrated. According to the invention, in terms of circuitry, a Schottky contact 11 is formed between the selection transistor 4 and the storage capacitor 3, the diode circuit symbol of the Schottky contact being illustrated in FIG. 3. Although the diode current can normally flow only in one direction, as a result of an electric field induced by the gate electrode, the diode property of preventing currents in the reverse direction is reduced due to the reduced depletion layer thickness, so that the storage capacitors 3 can be both written to and read from.

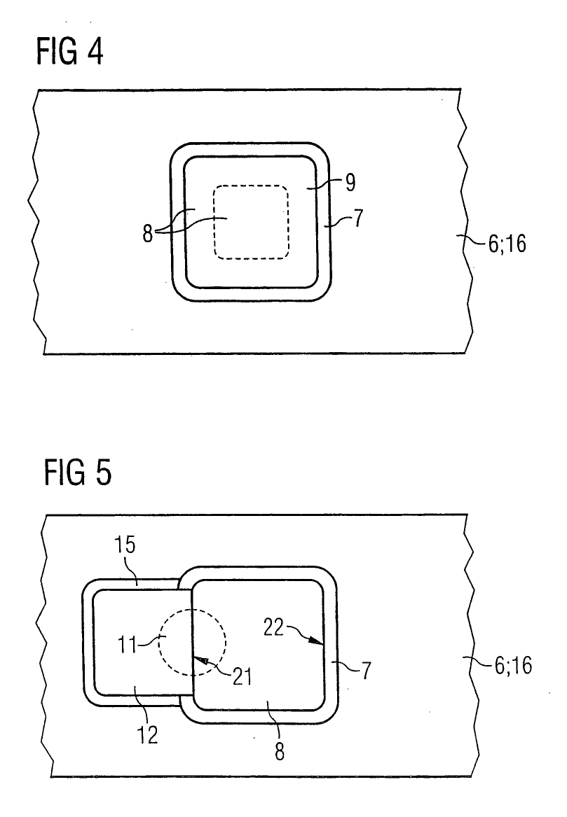

FIGS. 4 and 5 show cross sections of the semiconductor memory from FIG. 1 at different levels H1 and H2 parallel to the substrate surface 26. FIG. 4 illustrates the section at a level H1 above the metallic contact connection 12. At this level, the region 8 made of semiconductor material that is formed in pillar-type fashion is surrounded annularly by the gate dielectric 7 and, then by the material of the gate electrode 16 or the word line 6. Since the gate electrode surrounds the region 8 made of semiconductor material, the transistor channel 9 has a relatively larger cross section, which, as illustrated in FIG. 1, flows in the direction of the double arrow 14 relatively perpendicular to the surface 26 of the semiconductor substrate 13. Due to the annular channel cross section, larger charge quantities can be transported in a shorter time.

FIG. 5 shows a cross section at level H2 of the Schottky contact 11 between the electrical contact connection 12 and the region 8 made of semiconductor material. The Schottky contact 11 is provided on one side 21 of the region 8; on the other, opposite side 22 is the gate dielectric 7 and, behind the gate dielectric 7 is the gate electrode 16 or the word line 6. The electric field that is induced from there through the gate electrode 16 through the region 8 through to the Schottky diode 11, as illustrated in FIG. 1, opens the Schottky diode for reading or storing a digital information item.

With such a Schottky contact 11 and by dispensing with a second source/drain implantation in the region made of semiconductor material for forming a transistor channel, the intensity of leakage currents, in particular, of the subthreshold current, can also be reduced in other designs of integrated semiconductor memories. The effective channel length is increased; at the same time, leakage currents toward the buried outer electrode of the storage capacitors are impeded. The storage capacitors can be arranged in relatively greater spatial proximity to the selection transistor. As a result, the storage capacitance is increased and the read-out speed is increased. That metallic contact connection has a relatively higher electrical conductivity than conventional polysilicon fillings also contributes.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### List of Reference Symbols

1 semiconductor memory
2 memory cell
3 storage capacitor
4 selection transistor
5 bit line
6 word line
7 gate dielectric
8 region made of semiconductor material
9 transistor channel
10 source/drain implantation on the bit line side
11 schottky contact
12 metallic contact connection
13 semiconductor substrate
14 current flow direction
15 insulation
16 gate electrode
17 capacitor dielectric
18 interface
19 buried electrode
20 outer capacitor electrode
21, 22 opposite sides of the region 8
23 inner capacitor electrode
25 trench isolation
26 surface of the semiconductor substrate
Ec lower conduction band edge
E_{F} fermi energy
Ev upper valence band edge
G trench
H1, H2 levels
n-fet field effect transistor
p1, . . . , p5 electrical potentials

1. An integrated semiconductor memory, comprising:
a memory cell with a storage capacitor and a selection transistor, the selection transistor being driven by a bit line and a word line, the selection transistor having a region made of semiconductor material which adjoins a gate dielectric, a transistor channel being formed in the semiconductor material, a source/drain implantation being disposed therein which electrically contacts the bit line; and
a Schottky contact provided between the selection transistor and the storage capacitor wherein the region made of semiconductor material is free of dopants of a source/drain implantation proximate to the Schottky contact.

2. The semiconductor memory as claimed in claim 1, wherein the selection transistor consists of the source/drain implantation, which electrically contacts the bit line, in the region made of semiconductor material.

3. The semiconductor memory as claimed in claim 1, wherein the Schottky contact is formed between an interface between the region made of semiconductor material and a metallic contact connection.

4. The semiconductor memory as claimed in claim 1, wherein the Schottky contact is formed directly at the interface of the region made of semiconductor material.

5. The semiconductor memory as claimed in claim 1, wherein the storage capacitor is a trench capacitor formed in a semiconductor substrate, and the selection transistor is arranged such that a transistor channel with a current flow direction running perpendicular to the substrate surface of the semiconductor substrate can be formed in the region made of semiconductor material.

6. The semiconductor memory as claimed in claim 3, wherein the region made of semiconductor material is formed in pillar-type fashion and is covered on a periphery with the gate dielectric at a first level above the metallic contact connection.

7. The semiconductor memory as claimed in claim 6, wherein the region made of semiconductor material that is covered with the gate dielectric is annularly surrounded by a gate electrode.

8. The semiconductor memory as claimed in claim 7, wherein, in an inactivated state of the semiconductor memory, the gate electrode is biased with an electrical potential;
the Schottky contact effects blocking; and
the storage capacitor is electrically insulated from the selection transistor.

9. The semiconductor memory as claimed in claim 6, wherein, when the gate electrode is biased by a gate potential that opens the selection transistor, the Schottky contact is opened.

10. The semiconductor memory as claimed in claim 9, wherein the gate electrode extends on a side of the region made of semiconductor material opposite to the metallic contact connection into a second level of the Schottky contact.

11. The semiconductor memory as claimed in claim 1, wherein the region made of semiconductor material is part of the semiconductor substrate, and the word line is introduced into a trench surrounding the region made of semiconductor material.

12. The semiconductor memory as claimed in claim 1, wherein the selection transistor is a field effect transistor and the semiconductor memory is a dynamic random access memory.

13. The semiconductor memory as claimed in claim 4, wherein the region made of semiconductor material is formed in pillar-type fashion and is covered on a periphery with the gate dielectric at a first level above the metallic contact connection.

14. The semiconductor memory as claimed in claim 5, wherein the region made of semiconductor material is formed in pillar-type fashion and is covered on a periphery with the gate dielectric at a first level above the metallic contact connection.

15. The semiconductor memory as claimed in claim 13, wherein the region made of semiconductor material covered with the gate dielectric is annularly surrounded by a gate electrode.

16. The semiconductor memory as claimed in claim 14, wherein the region made of semiconductor material covered with the gate dielectric is annularly surrounded by a gate electrode.

17. The semiconductor memory as claimed in claim 15, wherein, in an inactivated state of the semiconductor memory, the gate electrode is biased with an electrical potential;
the Schottky contact effects blocking; and
the storage capacitor is electrically insulated from the selection transistor.

18. The semiconductor memory as claimed in claim 16, wherein, in an inactivated state of the semiconductor memory, the gate electrode is biased with an electrical potential;
the Schottky contact effects blocking; and
the storage capacitor is electrically insulated from the selection transistor.
